(19) United States
(12) Patent Application Publication
(10) Pub. No.: US 2024/0298473 A1
(43) Pub. Date: Sep. 5, 2024

(54) DISPLAY PANEL AND METHOD FOR MANUFACTURING THE SAME, AND DISPLAYING DEVICE

(71) Applicants: Hefei BOE Joint Technology Co., Ltd., Hefei, Anhui (CN); BOE Technology Group Co., Ltd., Beijing (CN)

(72) Inventor: Wenbin Jia, Beijing (CN)

(73) Assignees: Hefei BOE Joint Technology Co., Ltd., Hefei, Anhui (CN); BOE Technology Group Co., Ltd., Beijing (CN)

(21) Appl. No.: 18/025,538

(22) PCT Filed: May 30, 2022
(86) PCT No.: PCT/CN2022/096055

§ 371 Date: Mar. 9, 2023

(51) Int. Cl. H10K 59/122; H10K 59/12; H10K 59/35; H10K 71/13

(52) U.S. Cl. CPC H10K 59/122; H10K 59/1201; H10K 59/353; H10K 71/135

(57) ABSTRACT

A display panel and a method for manufacturing the same, and a displaying device, which relates to the technical field of displaying. The display panel includes a substrate base plate, and a pixel definition layer. The pixel definition layer is configured for defining a plurality of sub-pixel openings, and includes: primary pixel blocking walls and a plurality of sub-pixel blocking walls that intersect. The plurality of sub-pixel blocking walls include first sub-pixel blocking walls and second sub-pixel blocking walls, both of heights of the first sub-pixel blocking walls and heights of the second sub-pixel blocking walls are less than heights of the primary pixel blocking walls, and the first sub-pixel blocking walls and the second sub-pixel blocking walls have different heights and/or different materials.

### TECHNICAL FIELD

The present disclosure relates to the technical field of displaying and, more particularly, to a display panel, a method for manufacturing the same, and a displaying device.

### BACKGROUND

In the Organic Light Emitting Diode (OLED) technique, the Red, Green, Blue (RGB) pixel light emission is usually performed by using organic light emitting devices. Currently, the fabrication of the pixels may include manufacturing the pixel definition layer (PDL) on the electrodes of the base plate in advance, to define the ink droplets to accurately flow into the specified R/G/B sub-pixel regions. In conventional pixel structures, with the increase of the pixel resolution, the pixel openings are required to be reduced, and the film-formation uniformity of the pixels continuously decreases, which affects the life and the quality of the product. Therefore, currently the technical difficulty is how to increase the uniformity of the distribution of the pixels in the display panel.

### SUMMARY

The present disclosure provides a display panel, wherein the displaying base plate includes a substrate base plate, and a pixel definition layer disposed on one side of the substrate base plate, and the pixel definition layer is for defining a plurality of sub-pixel openings;
the pixel definition layer includes:
primary pixel blocking walls configured for separating sub-pixel openings that display different colors; and
a plurality of sub-pixel blocking walls that are separately disposed; wherein the sub-pixel blocking walls intersect with the primary pixel blocking walls, and are configured for separating the sub-pixel openings that display same colors;
wherein the plurality of sub-pixel blocking walls include first sub-pixel blocking walls and second sub-pixel blocking walls, both of heights of the first sub-pixel blocking walls and heights of the second sub-pixel blocking walls are less than heights of the primary pixel blocking walls, and the first sub-pixel blocking walls and the second sub-pixel blocking walls have different heights and/or different materials.

Optionally, the heights of the first sub-pixel blocking walls are less than the heights of the second sub-pixel blocking walls, and/or lyophilicities of the first sub-pixel blocking walls is greater than lyophilicities of the second sub-pixel blocking walls.

Optionally, at least one of the first sub-pixel blocking walls is separately disposed between two neighboring second sub-pixel blocking walls.

Optionally, the pixel definition layer further includes third sub-pixel blocking walls; and
the third sub-pixel blocking walls are disposed on a surface of one side of two first sub-pixel blocking walls on an outmost side of the substrate base plate that is away from the substrate base plate, and orthographic projections of the second sub-blocking walls on the substrate base plate are located within an area of orthographic projections on the substrate base plate of two first sub-pixel blocking walls on the outmost side of the substrate base plate.

Optionally, the third sub-pixel blocking walls and the primary pixel blocking walls have an equal height and a same material.

Optionally, the heights of the second sub-pixel blocking walls are greater than or equal to 0.5 time the heights of the primary pixel blocking walls, and less than or equal to the heights of the primary pixel blocking walls; and/or
the heights of the first sub-pixel blocking walls are greater than or equal to 0.1 time the heights of the primary pixel blocking walls, and less than or equal to 0.4 time the heights of the primary pixel blocking walls.

Optionally, the heights of the first sub-pixel blocking walls are greater than or equal to 10 nm, and less than or equal to 0.3 μm; and/or
the heights of the second sub-pixel blocking walls are greater than or equal to 50 nm, and less than or equal to 0.6 μm; and/or
the heights of the primary pixel blocking walls are greater than or equal to 100 nm, and less than or equal to 5 μm.

Optionally, liquid contact angles of the second sub-blocking walls are greater than or equal to 38°, and less than or equal to 45°; and/or
the liquid contact angles of the second sub-pixel blocking walls are greater than or equal to 10°, and less than or equal to 38°; and/or
liquid contact angles of the first sub-pixel blocking walls are greater than or equal to 0°, and less than or equal to 5°.

Optionally, the primary pixel blocking walls include fluorine containing PI or a resin; and/or
the first sub-pixel blocking walls include any one of PI, acrylic, a resin and an inorganic film layer; and/or
the second sub-pixel blocking walls include PI or a resin.

Optionally, neighboring sub-pixel openings that have different colors are arranged in a row direction, and neighboring sub-pixel openings that have same colors are arranged in a column direction; and
each of the sub-pixel openings includes longer side edges, and the longer side edges extend in the column direction.

Optionally, the displaying base plate further includes an organic-material layer disposed inside each of the sub-pixel openings;
a surface of one side of the organic-material layer that is away from the substrate base plate is higher than a surface of one side of the first sub-pixel blocking walls that is away from the substrate base plate, and lower than a surface of one side of the primary pixel blocking walls that is away from the substrate base plate; and
the heights of the first sub-pixel blocking walls are less than the heights of the second sub-pixel blocking walls.

The present disclosure further provides a method for manufacturing a display panel, wherein the method includes:
providing a substrate base plate; and
forming a pixel definition layer on one side of the substrate base plate, wherein the pixel definition layer is configured for defining a plurality of sub-pixel openings;
wherein the pixel definition layer includes: primary pixel blocking walls for separating sub-pixel openings of different colors; and
a plurality of sub-pixel blocking walls that are separately disposed; wherein the sub-pixel blocking walls intersect with the primary pixel blocking walls, and are configured for separating the sub-pixel openings of same colors;
wherein the plurality of sub-pixel blocking walls include first sub-pixel blocking walls and second sub-pixel blocking walls, both of heights of the first sub-pixel blocking walls and heights of the second sub-pixel blocking walls are less than heights of the primary pixel blocking walls, and the first sub-pixel blocking walls and the second sub-pixel blocking walls have different heights and/or different materials.

Optionally, the step of forming the pixel definition layer on one side of the substrate base plate includes:
by using a first patterning process, forming the first sub-pixel blocking walls and the second sub-pixel blocking walls on one side of the substrate base plate; and
by using a second patterning process, forming the primary pixel blocking walls on a same side of the substrate base plate, and, forming third sub-pixel blocking walls on one side of two first sub-pixel blocking walls on an outmost side of the substrate base plate that is away from the substrate base plate, wherein orthographic projections of the third sub-pixel blocking walls on the substrate base plate are located within an area of orthographic projections on the substrate base plate of two first sub-pixel blocking walls on the outmost side of the substrate base plate.

Optionally, after the step of forming the pixel definition layer on one side of the substrate base plate, the method further includes:
by using an ink-jet printing process, forming an organic-material layer inside each of the sub-pixel openings.

The present disclosure further provides a displaying device, wherein the displaying device includes the display panel according to any one of the above embodiments.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work. It should be noted that the scales in the drawings are merely illustrative and do not indicate the actual scales.

FIG. 1 shows a schematic planar structural diagram of a pixel definition layer in the related art;

FIG. 2 shows a schematic sectional structural diagram of a display panel in the related art;

FIG. 3 shows a schematic planar structural diagram of another pixel definition layer in the related art;

FIG. 4 shows a schematic sectional structural diagram of another display panel in the related art;

FIG. 5 schematically shows a schematic planar structural diagram of a pixel defining structure according to the present disclosure;

FIG. 6 schematically shows a schematic sectional structural diagram of a display panel according to the present disclosure;

FIG. 7 schematically shows another schematic sectional structural diagram of a display panel according to the present disclosure;

FIG. 8 schematically shows a schematic comparison diagram of pixel evenness according to the present disclosure; and

FIG. 9 schematically shows a flow chart of the steps of a method for manufacturing a display panel according to the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the related art, the OLED film-formation modes mainly include the vapor-deposition manufacture procedure and the solution manufacture procedure. Currently, the vapor-deposition manufacture procedure has been applied in mass production, but that technique has expensive materials and a low material utilization ratio, which increases the cost of product development. Moreover, the OLED film-formation modes of the solution manufacture procedure mainly include ink-jet printing, nozzle spread coating, spin coating, screen printing and so on.

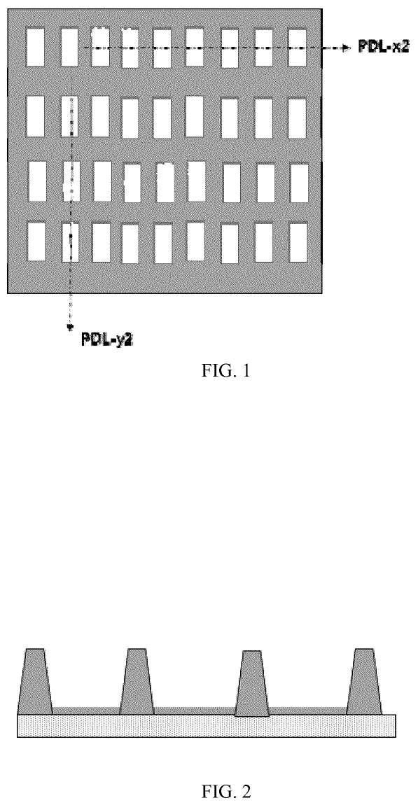

Referring to FIG. 1, FIG. 1 shows a schematic planar structural diagram of a pixel definition layer in the related art. As shown in FIG. 1, in the currently commonly used ink-jet printing process, the ink droplets are printed into the pixel region, and the sub-pixel openings corresponding to the pixel region are obtained by being defined by a pixel definition layer. If the pixels defined by the pixel defining structure have a higher resolution, a higher precision of the ink-jet printing is required.

Referring to FIG. 2, FIG. 2 shows a schematic sectional structural diagram of a display panel in the related art. As shown in FIG. 2, from the sectional structure of the display panel at the plane where PDL-x2 is located, it can be seen that the sub-pixel openings are independent of each other and are not in communication with each other. As limited by the hardware of the printer nozzles, the stabilities of each of the nozzles cannot ensure that all of the volumes of the ink droplets entering each of the sub-pixel openings are equal, and therefore it cannot be ensured that the volumes of each of the obtained pixels are equal, which results in a nonuniform effect of displaying. Furthermore, while high-resolution products are having increasingly higher requirements on the printing precision, the requirements on the printing precision of the shorter side edges of the pixels and the directions in which and the longer side edges of the pixels are located are increasingly higher.

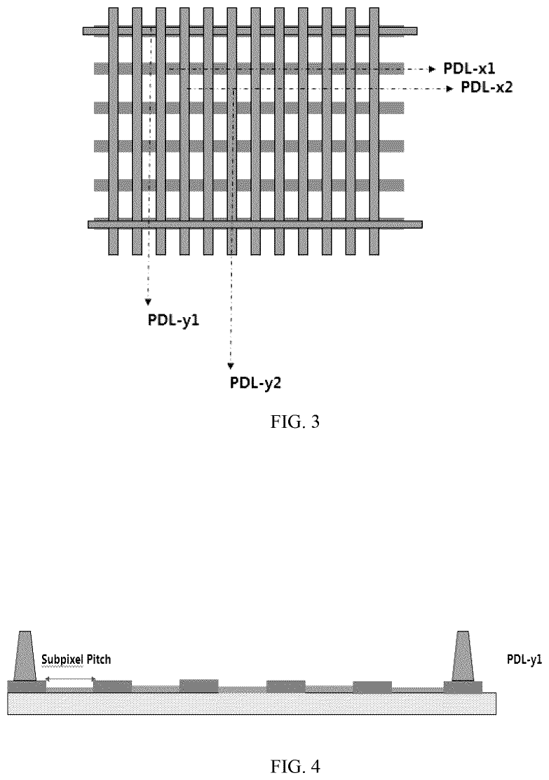

Referring to FIG. 3, FIG. 3 shows a schematic planar structural diagram of another pixel definition layer in the related art. As shown in FIG. 3, the inventor has found that, by causing the ink droplets of the sub-pixels of the same color in each of the longitudinal columns to flow through each other, the ink droplets of the sub-pixels of the same color can be evenly distributed to each of the sub-pixel openings in the same one column, to reduce the difference in the volumes of the ink droplets of the sub-pixels, and in turn reduce the cross-color and the thin dark lines of printing. Furthermore, as influenced by the atmosphere, the film-formation uniformity of the printing is increased, and the requirement on the hardware precision of the printer station can be reduced.

Referring to FIG. 4, FIG. 4 shows a schematic sectional structural diagram of another display panel in the related art. In the Line Bank pixel arrangement exhibited by the sectional structure of the display panel at the plane where PDL-y1 is located as shown in FIG. 4, the inventor has further found that, if the ink droplets of the sub-pixels of the same color are caused to flow through each other, there are the following problems. Firstly, in of process of the VCD drying of the display panel, the solvent of the ink droplets at the edge pixels evaporates too quickly, and therefore the ink droplets in the middle move toward the edges, and simultaneously carry the solute to flow toward the edges of the display panel which causes that the film thicknesses at the edges of the display panel are not even, to result in the problem of nonuniform displaying. Secondly, in the practical processing process, the table top of the printer station usually has a high flatness, and has difficulty in reaching an idealized low numerical value. Moreover, the unevenness of the printer station causes that the pixels on the higher side flow toward the lower side, and the film thicknesses of the pixels on the higher and lower sides are different largely, which also results in the problem of nonuniform displaying. An ideal Line Bank pixel arrangement requires that the pixel liquid of the same one column can flow smoothly in printing, and has a poor fluidity in pixel drying. Obviously, the conventional display panels cannot balance the two requirements.

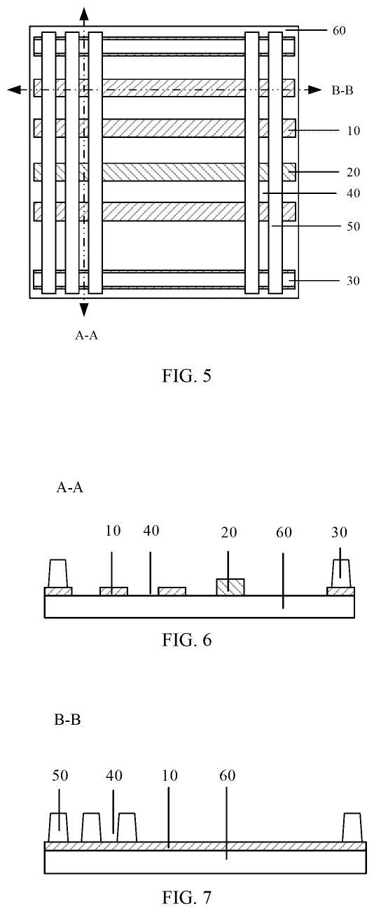

In order to solve the above problems, the present disclosure provides a display panel. Referring to FIG. 5, FIG. 5 schematically shows a schematic planar structural diagram of a pixel defining structure according to the present disclosure. As shown in FIG. 5, the display panel includes a substrate base plate 50, and a pixel definition layer disposed on one side of the substrate base plate 50, and the pixel definition layer is configured for defining a plurality of sub-pixel openings 40.

The display panel may include an organic-light-emitting-diode displaying base plate or a color-film base plate of a liquid-crystal panel, to perform light emitting displaying.

The pixel definition layer includes:
primary pixel blocking walls 60 configured for separating the sub-pixel openings 40 of different colors; and
a plurality of sub-pixel blocking walls that are separately disposed. The sub-pixel blocking walls intersect with the primary pixel blocking walls 60, and are configured for separating sub-pixel openings 40 of same colors.

Illustrative description will be made with reference to FIG. 5. A plurality of primary pixel blocking walls 60 that are arranged in parallel in the longitudinal direction and a plurality of sub-pixel blocking walls that are arranged in parallel in the transverse direction may form a plurality of sub-pixel openings 40. The sub-pixel openings 40 may be used to disposed organic-material layers, and the organic-material layers may include luminescent pixel materials, i.e., pixels. The displaying colors of the luminescent pixel materials of the sub-pixel openings 40 between two neighboring primary pixel blocking walls 60 are the same. As an example, the color may be red, green or blue.

The sub-pixel openings 40 of the same displaying color may be provided with organic-material layers of the same emitted-light colors.

Referring to FIG. 6, FIG. 6 schematically shows a schematic sectional structural diagram of a display panel according to the present disclosure. Referring to FIG. 7, FIG. 7 schematically shows another schematic sectional structural diagram of a display panel according to the present disclosure. FIG. 6 shows the sectional structure of the display panel at the plane where A-A is located. FIG. 7 shows the sectional structure of the display panel at the plane where B-B is located. The plurality of sub-pixel blocking walls include first sub-pixel blocking walls 10 and second sub-pixel blocking walls 20, both of the heights of the first sub-pixel blocking walls 10 and the heights of the second sub-pixel blocking walls 20 are less than the heights of the primary pixel blocking walls 60, and the first sub-pixel blocking walls 10 and the second sub-pixel blocking walls 20 have different heights and/or different materials.

By using the embodiment of the present disclosure, both of the heights of the first sub-pixel blocking walls 10 and the heights of the second sub-pixel blocking walls 20 are less than the heights of the primary pixel blocking walls 60, which can effectively prevent overflowing of the pixels, and can prevent mixing between the pixels of different colors in the manufacturing process.

The lyophilicities of the primary pixel blocking walls 60 may be greater than the lyophilicities of the sub-pixel blocking walls, which can further prevent overflowing of the pixels, and can prevent mixing between every two lines of the pixels of different colors in the manufacturing process.

It should be noted that the “A and/or B” in the embodiments of the present disclosure includes at least any one of “A” and “B”, and may particularly include the three cases of “A and B”, “4” and “B”.

The substrate base plate 50 may be used to, as the bottom of the sub-pixel openings 40, define the positions of the pixels together with the primary pixel blocking walls 60 and the pixel definition layer. The substrate base plate 50 may include a base plate and electrodes.

The heights of the sub-pixel blocking walls or the heights of the primary pixel blocking walls 60 in the pixel definition layer according to the present disclosure refers to the height in the normal direction of the substrate base plate 50 when the pixel definition layer is in the same one plane, for example, at the surface of one side of the substrate base plate 50.

The lyophilicity according to the present disclosure refers to the affinity of a material surface to a liquid, which may be inversely proportional to the lyophobicity of the material surface, and, in the present disclosure, may refer to the affinity of a material surface to the pixel liquid in ink-jet printing. The lyophilicity is related to the surface energy or the surface tension of the material surface, and if the lyophilicity is higher, the fluidity of the liquid flowing through that position of the material is poorer.

The plurality of sub-pixel blocking walls may be perpendicular to the primary pixel blocking walls 60.

The second sub-pixel blocking walls 20 of the higher height and/or the lower lyophilicity can serve to buffer the pixel ink droplets and reduce the fluidity of the pixel liquid during the pixel drying. The first sub-pixel blocking walls 10 of the lower height and/or the higher lyophilicity can serve to realize same-column flowing and adjust the volume difference between the pixel ink droplets in neighboring sub-pixel openings 40 in the ink-jet printing of the pixels.

The pixels may include red-color sub-pixels, green-color sub-pixels and blue-color sub-pixels, and may also include a white-color pixel layer. The sub-pixels of the single colors may be used to emit light, to display the corresponding colors. The sub-pixels of the colors may be sequentially alternately arranged in the transverse direction, to form the combination of red-yellow-blue three-color pixels, to complete the corresponding frame displaying with the corresponding grayscale proportion or brightness proportion.

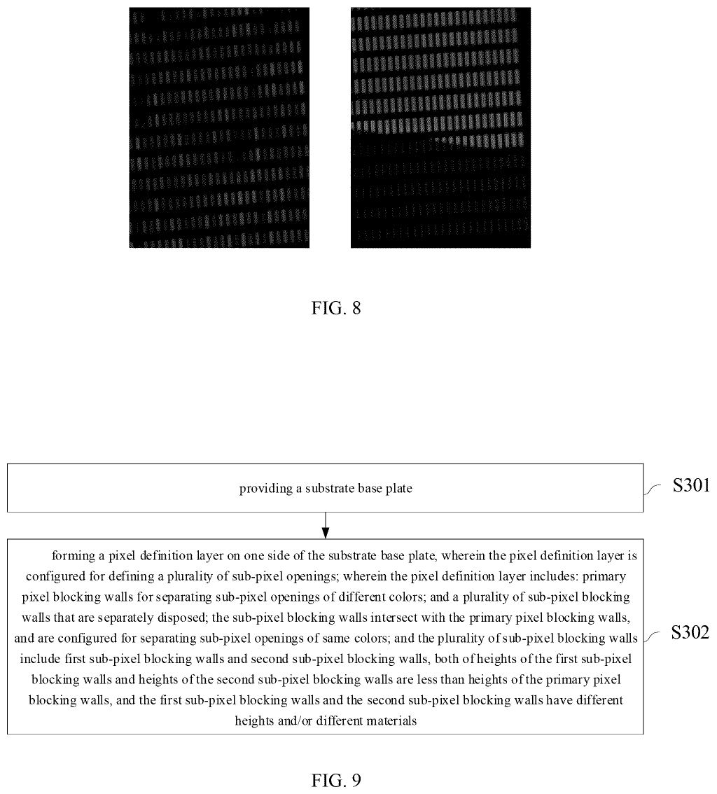

Referring to FIG. 8, FIG. 8 schematically shows a schematic comparison diagram of pixel evenness according to the present disclosure. As shown in FIG. 8, by using the above embodiments, the present disclosure provides the primary pixel blocking walls 60 and at least 2 types of sub-pixel blocking walls of different heights and/or different lyophilicities, and the height of the organic-material layers is greater than that of the sub-pixel blocking walls and less than that of the primary pixel blocking walls 60. Accordingly, the pixels can maintain a good fluidity in the processing process, to enable the pixels in the sub-pixel openings 40 to have even volumes. Furthermore, in the process of pixel drying, the flowing of the pixels toward one side of the display panel is reduced, to further improve the uniformity of the emitted lights of the pixels, thereby improving the effect of displaying of the display panel. Furthermore, the present disclosure can solve the problem of printer stations of an insufficient flatness, which, while lowering the requirement on the flatness of the printer stations, can improve the printing process window and the device adjustment room, which is especially suitable for mass production of the printing of large-size OLED panels.

The present disclosure, by disposing the two types of sub-pixel blocking walls of the different heights and/or lyophilicities, can maintain the proper fluidity of the pixels while reducing the difficulty in the fabrication. Accordingly, in an alternative embodiment, the present disclosure further provides sub-pixel blocking walls, wherein the heights of the first sub-pixel blocking walls 10 are less than the heights of the second sub-pixel blocking walls 20, and/or the lyophilicities of the first sub-pixel blocking walls 10 are greater than the lyophilicities of the second sub-pixel blocking walls 20.

Particularly, the first sub-pixel blocking walls 10 have a lower height and/or a higher lyophilicity, so the pixel liquid, in the processing by ink-jet printing, can flow uniformly over the first sub-pixel blocking walls 10, and the volumes of the liquids in the pixels in the sub-pixel openings 40 on the two sides of the first sub-pixel blocking walls 10 are substantially equal after they have flowed to be even. Moreover, the second sub-pixel blocking walls 20 have a higher height and/or a lower lyophilicity, so in the drying of the pixel liquid, in the case in which when the display panel is placed on an uneven station, the pixel liquid flows toward one side, or in the case in which, with the evaporation at the edges, the pixel liquid flows toward one side, the pixel liquids of the pixels on the two sides of the second sub-pixel blocking walls 20 do not flow or flow at a low flowing speed, to further prevent nonuniform displaying.

In order to further facilitate the fabrication, the sub-pixel blocking walls may be two types of pixel definition layer that are arranged in a same layer. Accordingly, in an alternative embodiment, the present disclosure further provides sub-pixel blocking walls, wherein the first sub-pixel blocking walls 10 include the first sub-pixel blocking walls 10, and the second sub-pixel blocking walls 20 include the second sub-pixel blocking walls 20. The heights of the first sub-pixel blocking walls 10 are less than the heights of the second sub-pixel blocking walls 20, and/or the lyophilicities of the first sub-pixel blocking walls 10 are greater than the lyophilicities of the second sub-pixel blocking walls 20.

The pixel defining structure may also be arranged in a same layer as the sub-pixel blocking walls. Accordingly, in an alternative embodiment, the present disclosure further provides a pixel defining structure of different heights, wherein the primary pixel blocking walls 60 include the first sub-pixel blocking walls 10 extending to the periphery of a first pixel region and second sub-blocking walls located on the first sub-pixel blocking walls 10. The heights of the second sub-blocking walls are greater than or equal to the heights of the second sub-pixel blocking walls 20, and/or the lyophilicities of the second sub-blocking walls are less than or equal to the lyophilicities of the second sub-pixel blocking walls 20.

Preferably, in order to facilitate the convergence of the pixels of the same color, in the direction of the plane where the normal of the substrate base plate 5060 is located, the shape of the section of the second sub-pixel blocking walls among the primary pixel blocking walls 60 may be a trapezoid, and, further, may be an isosceles trapezoid, wherein the lower bottom side of the trapezoid is located on the side closer to the substrate base plate 5060.

The first sub-pixel blocking walls 10 may be fabricated in one step. Therefore, the first sub-pixel blocking walls 10 within the first pixel region are fabricated, and that part of the first sub-pixel blocking walls 10 is used as the first sub-pixel blocking walls 10. The first sub-pixel blocking walls 10 at the periphery of the first pixel region may also be fabricated simultaneously, and that part of the first sub-pixel blocking walls 10 is used as a part of the primary pixel blocking walls 60, to increase the heights of the primary pixel blocking walls 60.

In the embodiments of the present disclosure, all of the heights of the sub-pixel blocking walls and the primary pixel blocking walls 60, the lyophilicities of the sub-pixel blocking walls and the primary pixel blocking walls 60, and the types, the quantities and the particular arrangement and distribution modes of the sub-pixel blocking walls can influence the fluidity of the pixels of the display panel. In order to enable the pixels of the display panel to have a moderate fluidity, one or more of the above factors may be adjusted.

The sub-pixel blocking walls of a higher height or a higher lyophilicity can restrict the fluidity of the pixels, but if the sub-pixel blocking walls of a higher height or a higher lyophilicity are arranged too closely, that makes it difficult for the pixels to flow in the printing process. Accordingly, in an alternative embodiment, the present disclosure further provides a display panel, wherein at least one of the first sub-pixel blocking walls 10 is separately disposed between two neighboring second sub-pixel blocking walls 20.

If more first sub-pixel blocking walls 10 are separately disposed between the second sub-pixel blocking walls 20, that indicates that the first sub-pixel blocking walls 10 have a higher crowding level, whereby there are more sub-pixel openings 40 between two neighboring second sub-pixel blocking walls 20 in the same column, and the pixels have a higher fluidity. As an example, if one sub-pixel blocking wall 10 is disposed every other 2 second sub-pixel blocking walls 20, then 3 sub-pixel openings 40 exist between two neighboring first sub-pixel blocking walls 10 in the same column.

In order to further reduce the regions of the display panel that have nonuniform light emission, in an alternative embodiment, the crowding levels of the first sub-pixel blocking walls 10 within different regions of the same one display panel may be unequal. In other words, the quantities of the sub-pixel openings 40 separately disposed between every two neighboring first sub-pixel blocking walls 10 may be unequal, so as to, for different situations of the light emission of the display panel, locally regulate the fluidity of the pixels, thereby improving the overall effect of displaying of the display panel.

In an alternative embodiment, the present disclosure further provides a display panel, wherein the pixel definition layer further includes third sub-pixel blocking walls.

The third sub-pixel blocking walls are disposed on the surface of the side of two first sub-pixel blocking walls 10 on the outmost side of the substrate base plate 50 that is away from the substrate base plate 50, and the orthographic projections of the second sub-blocking walls on the substrate base plate 50 are located within the area of the orthographic projections on the substrate base plate 50 of two first sub-pixel blocking walls 10 on the outmost side of the substrate base plate 50.

Accordingly, in the embodiments of the present disclosure, the third sub-pixel blocking walls are disposed on the two first sub-pixel blocking walls 10 on the outmost side of the substrate base plate 50. By disposing the higher pixel blocking walls at the edge positions of the pixel region, the restriction on the flowing of the pixels in the direction of the primary pixel blocking walls 60 can be enhanced. Moreover, the restriction on the flowing of the pixels in the direction perpendicular to the primary pixel blocking walls 60 can be done by the primary pixel blocking walls 60 higher than the sub-pixel blocking walls.

Further, in an alternative embodiment, the third sub-pixel blocking walls and the primary pixel blocking walls 60 have an equal height and a same material. Accordingly, the third sub-pixel blocking walls may be fabricated simultaneously with the primary pixel blocking walls 60, which further reduces the complexity in the processing.

In an alternative embodiment, heights of the second sub-pixel blocking walls 20 are greater than or equal to 0.5 time the heights of the primary pixel blocking walls 60, and less than or equal to the heights of the primary pixel blocking walls 60; and/or
the heights of the first sub-pixel blocking walls 10 are greater than or equal to 0.1 time the heights of the primary pixel blocking walls 60, and less than or equal to 0.4 time the heights of the primary pixel blocking walls 60.

Particularly, at the positions where the primary pixel blocking walls 60 and the sub-pixel blocking walls intersect, overlapping pixel blocking walls may be formed, wherein the heights of the overlapping pixel blocking walls may be the sum of the heights of the primary pixel blocking walls 60 and the heights of the sub-pixel blocking walls.

Further, the present disclosure further provides exemplary heights of the pixel definition layer, wherein the heights of the first sub-pixel blocking walls 10 are greater than or equal to 10 nm, and less than or equal to 0.3 μm; and/or
the heights of the second sub-pixel blocking walls 20 are greater than or equal to 50 nm, and less than or equal to 0.6 μm; and/or
the heights of the primary pixel blocking walls 60 are greater than or equal to 100 nm, and less than or equal to 5 μm.

Accordingly, in an alternative embodiment, the present disclosure further provides a pixel defining structure of different lyophilicities, wherein the liquid contact angles of the second sub-blocking walls are greater than or equal to 38°, and less than or equal to 45°; and/or
liquid contact angles of the second sub-pixel blocking walls 20 are greater than or equal to 10°, and less than or equal to 38°; and/or
liquid contact angles of the first sub-pixel blocking walls 10 are greater than or equal to 0°, and less than or equal to 5°.

The liquid contact angle may refer to the included angle between the edge of the ink droplet formed by the pixel liquid at the material surface and the flat face of the material. If the liquid contact angle is larger, the lyophilicity is lower.

By using the above embodiments, the three types of specified pixel blocking walls of the different heights or lyophilicities can be employed to form the pixel definition layer according to the station surfaces of different flatnesses and the state of flowing of the pixel liquid in the drying process, which cannot only enable the pixel liquid to flow in the process of ink-jet printing, but also can reduce or prevent flowing of the pixel liquid in the drying process, to obtain sub-pixels that are evenly distributed to the largest extent. In other words, after the drying has been completed, the volumes of the pixels inside the sub-pixel openings 40 are equal or similar, whereby the effect of displaying that is uniform everywhere can be obtained.

In the embodiments of the present disclosure, the material of the primary pixel blocking walls 60 and the materials of each type of the sub-pixel blocking walls may be different. In order to cause the lyophilicities of the first sub-pixel blocking walls 10 to be greater than or equal to the lyophilicities of the second sub-pixel blocking walls 20, and cause the lyophilicities of the second sub-pixel blocking walls 20 to be greater than or equal to the lyophilicities of the primary pixel blocking walls 60, in an alternative embodiment, the present disclosure further provides a display panel, wherein the primary pixel blocking walls 60 include fluorine containing PI or a resin; and/or
the first sub-pixel blocking walls 10 include any one of PI, acrylic, a resin and an inorganic film layer; and/or
the second sub-pixel blocking walls 20 include PI or a resin.

In the present disclosure, PI refers to polyimide.

The liquid contact angle of a material may be changed by changing the fluorine content of the material. Therefore, the fluorine contents of the PI materials of the primary pixel blocking walls 60 and the first sub-pixel blocking walls 10 may be unequal.

When the heights of the second sub-pixel blocking walls 20 are greater than the heights of the first sub-pixel blocking walls 10, the lyophilicities of the second sub-pixel blocking walls 20 may be equal to the lyophilicities of the primary pixel blocking walls 60.

Optionally, the liquid contact angle of a material may also be changed by surface treatment.

Taking into consideration the commonly used arrangement modes of the pixel structures in display panels currently, for example, RGB arrangement or diamond arrangement, the sub-pixel openings 40 may be arranged in an array, to place the pixels. Accordingly, in an alternative embodiment, neighboring sub-pixel openings 40 that have different colors are arranged in a row direction, and neighboring sub-pixel openings 40 that have same colors are arranged in a column direction.

Each of the sub-pixel openings 40 includes longer side edges, and the longer side edges extend in the column direction.

The sub-pixel openings 40 may be elongate, and further include shorter side edges, and that the longer side edges extend in the column direction refers to that the sub-pixel openings 40 in the same one column are connected by the shorter side edges.

The pixel arrangement of the display panel is performed according to the colors, wherein merely the pixels of the same colors can flow, and the pixels of different colors are required to be alternately arranged, and the pixels of different brightness proportions in one pixel combination cooperate to display the required color and brightness. Therefore, in an alternative embodiment, the pixel layers inside the sub-pixel openings 40 arranged in the column direction are of the same material, to display the same color.

Referring to FIG. 9, FIG. 9 is a flow chart of the steps of the method for manufacturing a display panel according to an embodiment of the present disclosure. As shown in FIG. 9, by referring to the above embodiments, on the basis of the similar inventive concept, an embodiment of the present disclosure further provides a method for manufacturing a display panel, wherein the method includes:

Step S301: providing a substrate base plate 50.

Step S302: forming a pixel definition layer on one side of the substrate base plate 50, wherein the pixel definition layer is for defining a plurality of sub-pixel openings 40.

The pixel definition layer includes: primary pixel blocking walls 60 configured for separating sub-pixel openings 40 of different colors; and
a plurality of sub-pixel blocking walls that are separately disposed.

The sub-pixel blocking walls intersect with the primary pixel blocking walls 60, and are configured for separating sub-pixel openings 40 of same colors. The plurality of sub-pixel blocking walls include first sub-pixel blocking walls 10 and second sub-pixel blocking walls 20, both of the heights of the first sub-pixel blocking walls 10 and the heights of the second sub-pixel blocking walls 20 are less than the height of the primary pixel blocking walls 60, and the first sub-pixel blocking walls 10 and the second sub-pixel blocking walls 20 have different heights and/or different materials.

Particularly, two types of sub-pixel blocking walls may be fabricated at a same time, and may also be fabricated separately, and the fabrications of the different sub-pixel blocking walls may not have a fixed sequence.

Taking into consideration that the primary pixel blocking walls 60 are required to define all of the pixels of the display panel therewithin, the primary pixel blocking walls 60 are required to be higher than the other pixel defining structures. Therefore, the primary pixel blocking walls 60 may be fabricated after the sub-pixel blocking walls have been fabricated.

Particularly, the pixel layers may be fabricated inside the sub-pixel openings 40 by ink-jet printing.

In the processing by ink-jet printing, the pixels may be ink droplets in the liquid state. Therefore, every two neighboring primary pixel blocking walls 60 can form one communicating region, whereby the pixel liquid can flow over the sub-pixel blocking walls and flow within the communicating region.

By using the above embodiments, the present disclosure can, by disposing the sub-pixel blocking walls of the different heights and/or lyophilicities, reduce the flowing of the ink droplets within the communicating region while ensuring the droplet equalization of the pixels, and may, according to the flatness of the station and the state of the flowing of the pixel liquid in the drying process, and according to the uniformity of the effect of displaying, further adjust the heights, the lyophilic positions and the densities of the sub-pixel blocking walls required to be fabricated.

Optionally, in the present disclosure, after the two types of sub-pixel blocking walls have been fabricated, the primary pixel blocking walls 60 may be fabricated. While the primary pixel blocking walls 60 are being fabricated, the third sub-pixel blocking walls may be fabricated synchronously. Accordingly, in an alternative embodiment, the present disclosure further provides a method for forming the pixel definition layer, wherein the method includes:

Step 401: by using a first patterning process, forming the first sub-pixel blocking walls 10 and the second sub-pixel blocking walls 20 on one side of the substrate base plate 50.

Step 402: by using a second patterning process, forming the primary pixel blocking walls 60 on the same side of the substrate base plate 50, and, forming third sub-pixel blocking walls on the side of two first sub-pixel blocking walls 10 on the outmost side of the substrate base plate 50 that is away from the substrate base plate 50, wherein the orthographic projections of the third sub-pixel blocking walls on the substrate base plate 50 are located within the area of the orthographic projections on the substrate base plate 50 of two first sub-pixel blocking walls 10 on the outmost side of the substrate base plate 50.

The height and the material of the third sub-pixel blocking walls may be the same as those of the primary pixel blocking walls 60. Therefore, the third sub-pixel blocking walls may be fabricated synchronously with the primary pixel blocking walls 60, so as to reduce the complexity in the fabrication.

The third sub-pixel blocking walls may also be connected to the primary pixel blocking walls 60 crosswise, to realize a better pixel leakproofness.

In an alternative embodiment, the present disclosure further provides a method for manufacturing the organic-material layer, wherein the method includes:
by using an ink-jet printing process, forming an organic-material layer inside each of the sub-pixel openings 40.

Particularly, the organic-material layers may be the pixel layers. The process may include, by ink-jet printing, printing the same material of the same emitted-light color inside the sub-pixel openings 40 of every column between two neighboring primary pixel blocking walls 60, to obtain the pixels arranged in an array.

At least one nozzle may be disposed at every row or every column, to perform ink printing synchronously, to increase the efficiency of the pixel fabrication.

It should be noted that the manufacturing method may further include more steps, which may be determined according to practical demands, and is not limited in the present disclosure. The detailed description on and the technical effects of the displaying device obtained by using the manufacturing method may refer to the above description on the displaying device, and are not discussed herein further.

By referring to the above embodiments, on the basis of the similar inventive concept, an embodiment of the present disclosure further provides a displaying device, wherein the displaying device comprises the display panel according to any one of the above embodiments. The embodiments of the description are described in the mode of progression, each of the embodiments emphatically describes the differences from the other embodiments, and the same or similar parts of the embodiments may refer to each other.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “comprising a . . . ” does not exclude additional same element in the process, method, article or device comprising the element.

The display panel, the method for manufacturing a display panel, and the displaying device according to the present disclosure have been described in detail above. The principle and the embodiments of the present disclosure are described herein with reference to the particular examples, and the description of the above embodiments is merely intended to facilitate to understand the method according to the present disclosure and its core concept. Moreover, for a person skilled in the art, according to the concept of the present disclosure, the particular embodiments and the range of application may be varied. In conclusion, the contents of the description should not be understood as limiting the present disclosure.

A person skilled in the art, after considering the description and implementing the invention disclosed herein, will readily envisage other embodiments of the present disclosure. The present disclosure aims at encompassing any variations, uses or adaptative alternations of the present disclosure, wherein those variations, uses or adaptative alternations follow the general principle of the present disclosure and include common knowledge or common technical means in the art that are not disclosed by the present disclosure. The description and the embodiments are merely deemed as exemplary, and the true scope and spirit of the present disclosure are presented by the following claims.

It should be understood that the present disclosure is not limited to the accurate structure that has been described above and shown in the drawings, and may have various modifications and variations without departing from its scope. The scope of the present disclosure is merely limited by the appended claims.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A display panel, wherein a displaying base plate comprises a substrate base plate, and a pixel definition layer disposed on one side of the substrate base plate, and the pixel definition layer is for defining a plurality of sub-pixel openings;
the pixel definition layer comprises:
primary pixel blocking walls configured for separating sub-pixel openings that display different colors; and
a plurality of sub-pixel blocking walls that are separately disposed; wherein the sub-pixel blocking walls intersect with the primary pixel blocking walls, and are configured for separating the sub-pixel openings that display same colors;
wherein the plurality of sub-pixel blocking walls include first sub-pixel blocking walls and second sub-pixel blocking walls, both of heights of the first sub-pixel blocking walls and heights of the second sub-pixel blocking walls are less than heights of the primary pixel blocking walls, and the first sub-pixel blocking walls and the second sub-pixel blocking walls have different heights and/or different materials.

2. The display panel according to claim 1, wherein the heights of the first sub-pixel blocking walls are less than the heights of the second sub-pixel blocking walls, and/or lyophilicities of the first sub-pixel blocking walls is greater than lyophilicities of the second sub-pixel blocking walls.

3. The display panel according to claim 2, wherein at least one of the first sub-pixel blocking walls is separately disposed between two neighboring second sub-pixel blocking walls.

4. The display panel according to claim 2, wherein the pixel definition layer further comprises third sub-pixel blocking walls; and
the third sub-pixel blocking walls are disposed on a surface of one side of two first sub-pixel blocking walls on an outmost side of the substrate base plate that is away from the substrate base plate, and orthographic projections of second sub-blocking walls on the substrate base plate are located within an area of orthographic projections on the substrate base plate of two first sub-pixel blocking walls on the outmost side of the substrate base plate.

5. The display panel according to claim 4, wherein the third sub-pixel blocking walls and the primary pixel blocking walls have an equal height and a same material.

6. The display panel according to claim 1, wherein the heights of the second sub-pixel blocking walls are greater than or equal to 0.5 time the heights of the primary pixel blocking walls, and less than or equal to the heights of the primary pixel blocking walls; and/or
the heights of the first sub-pixel blocking walls are greater than or equal to 0.1 time the heights of the primary pixel blocking walls, and less than or equal to 0.4 time the heights of the primary pixel blocking walls.

7. The display panel according to claim 6, wherein the heights of the first sub-pixel blocking walls are greater than or equal to 10 nm, and less than or equal to 0.3 μm; and/or
the heights of the second sub-pixel blocking walls are greater than or equal to 50 nm, and less than or equal to 0.6 μm; and/or
the heights of the primary pixel blocking walls are greater than or equal to 100 nm, and less than or equal to 5 μm.

8. The display panel according to claim 1, wherein liquid contact angles of the second sub-blocking walls are greater than or equal to 38°, and less than or equal to 45°; and/or
the liquid contact angles of the second sub-pixel blocking walls are greater than or equal to 10°, and less than or equal to 38°; and/or
liquid contact angles of the first sub-pixel blocking walls are greater than or equal to 0°, and less than or equal to 5°.

9. The display panel according to claim 1, wherein the primary pixel blocking walls comprise fluorine containing PI or a resin; and/or
the first sub-pixel blocking walls comprise any one of PI, acrylic, a resin and an inorganic film layer; and/or
the second sub-pixel blocking walls comprise PI or a resin.

10. The display panel according to claim 1, wherein neighboring sub-pixel openings that have different colors are arranged in a row direction, and neighboring sub-pixel openings that have same colors are arranged in a column direction; and
each of the sub-pixel openings comprises longer side edges, and the longer side edges extend in the column direction.

11. The display panel according to claim 1, wherein the display panel further comprises an organic-material layer disposed inside each of the sub-pixel openings;
a surface of one side of the organic-material layer that is away from the substrate base plate is higher than a surface of one side of the first sub-pixel blocking walls that is away from the substrate base plate, and lower than a surface of one side of the primary pixel blocking walls that is away from the substrate base plate; and
the heights of the first sub-pixel blocking walls are less than the heights of the second sub-pixel blocking walls.

12. A method for manufacturing a display panel, wherein the method comprises:
providing a substrate base plate; and
forming a pixel definition layer on one side of the substrate base plate, wherein the pixel definition layer is configured for defining a plurality of sub-pixel openings;
wherein the pixel definition layer comprises: primary pixel blocking walls for separating sub-pixel openings of different colors; and
a plurality of sub-pixel blocking walls that are separately disposed; wherein the sub-pixel blocking walls intersect with the primary pixel blocking walls, and are configured for separating the sub-pixel openings of same colors;
wherein the plurality of sub-pixel blocking walls include first sub-pixel blocking walls and second sub-pixel blocking walls, both of heights of the first sub-pixel blocking walls and heights of the second sub-pixel blocking walls are less than heights of the primary pixel blocking walls, and the first sub-pixel blocking walls and the second sub-pixel blocking walls have different heights and/or different materials.

13. The method for manufacturing the display panel according to claim 12, wherein the step of forming the pixel definition layer on one side of the substrate base plate comprises:
by using a first patterning process, forming the first sub-pixel blocking walls and the second sub-pixel blocking walls on one side of the substrate base plate; and
by using a second patterning process, forming the primary pixel blocking walls on a same side of the substrate base plate, and, forming third sub-pixel blocking walls on one side of two first sub-pixel blocking walls on an outmost side of the substrate base plate that is away from the substrate base plate, wherein orthographic projections of the third sub-pixel blocking walls on the substrate base plate are located within an area of orthographic projections on the substrate base plate of two first sub-pixel blocking walls on the outmost side of the substrate base plate.

14. The method for manufacturing the display panel according to claim 12, wherein after the step of forming the pixel definition layer on one side of the substrate base plate, the method further comprises:
by using an ink-jet printing process, forming an organic-material layer inside each of the sub-pixel openings.

15. A displaying device, wherein the displaying device comprises the display panel according to claim 1.

16. The displaying device according to claim 15, wherein the heights of the first sub-pixel blocking walls are less than the heights of the second sub-pixel blocking walls, and/or lyophilicities of the first sub-pixel blocking walls is greater than lyophilicities of the second sub-pixel blocking walls.

17. The displaying device according to claim 16, wherein at least one of the first sub-pixel blocking walls is separately disposed between two neighboring second sub-pixel blocking walls.

18. The displaying device according to claim 16, wherein the pixel definition layer further comprises third sub-pixel blocking walls; and
the third sub-pixel blocking walls are disposed on a surface of one side of two first sub-pixel blocking walls on an outmost side of the substrate base plate that is away from the substrate base plate, and orthographic projections of second sub-blocking walls on the substrate base plate are located within an area of orthographic projections on the substrate base plate of two first sub-pixel blocking walls on the outmost side of the substrate base plate.

19. The displaying device according to claim 18, wherein the third sub-pixel blocking walls and the primary pixel blocking walls have an equal height and a same material.

20. The displaying device according to claim 15, wherein the heights of the second sub-pixel blocking walls are greater than or equal to 0.5 time the heights of the primary pixel blocking walls, and less than or equal to the heights of the primary pixel blocking walls; and/or
the heights of the first sub-pixel blocking walls are greater than or equal to 0.1 time the heights of the primary pixel blocking walls, and less than or equal to 0.4 time the heights of the primary pixel blocking walls.
